(19) United States
(12) Patent Application Publication
(10) Pub. No.: US 2016/0312363 A1
(43) Pub. Date: Oct. 27, 2016

(54) LAMINATE FILM AND FLEXIBLE ELECTRONIC DEVICE

(71) Applicant: SUMITOMO CHEMICAL COMPANY, LIMITED, Tokyo (JP)

(72) Inventors: Yasuhiro YAMASHITA, Tsukuba-shi (JP); Yutaka ITO, Tsukuba-shi (JP); Hideaki NAKAJIMA, Ichihara-shi (JP)

(73) Assignee: SUMITOMO CHEMICAL COMPANY, LIMITED, Tokyo (JP)

(21) Appl. No.: 15/107,532

(22) PCT Filed: Dec. 11, 2014
(86) PCT No.: PCT/JP2014/083495

§ 371 Date: Jun. 23, 2016

(30) Foreign Application Priority Data
Dec. 26, 2013 (JP) 2013-268640

(51) Int. Cl. C23C 16/50; C23C 16/40; C23C 16/30

(52) U.S. Cl. CPC C23C 16/50; C23C 16/30; C23C 16/401; H01L 51/5253

(57) ABSTRACT

A laminated film includes a flexible base material, and at least one thin film layer formed on at least one of surfaces of the base material, and
the at least one thin film layer satisfies all of the following conditions (i) and (ii):
(i) a silicon atom (Si), an oxygen atom (O) and a nitrogen atom (N) are contained,
(ii) when X-ray photoelectron spectrometry is conducted for a surface of the thin film layer, an atomic number ratio of carbon atoms to silicon atoms calculated from a wide scan spectrum satisfies a condition represented by the following formula (1):

0<C/Si≦0.2 (1).

### TECHNICAL FIELD

The present invention relates to a laminated film and a flexible electronic device.

### BACKGROUND ART

A laminated film in which a thin film layer is formed (laminated) on a surface of a film-like base material in order to impart functionality to the base material is known. For example, a laminated film to which a gas barrier property is imparted by forming a thin film layer on a plastic film is suited for filling and packaging of articles such as foods and beverages, cosmetics, and detergents. In recent years, a laminated film in which a thin film of an inorganic oxide such as silicon oxide, silicon nitride, silicon oxynitride, and aluminum oxide is formed on one of surfaces of a base material film such as a plastic film has been proposed.

As a method for forming a thin film of an inorganic oxide on a surface of a plastic base material, deposition methods including physical vapor deposition (PVD) methods such as a vacuum evaporation method, a sputtering method, and an ion plating method, and chemical vapor deposition (CVD) methods such as a low pressure chemical vapor deposition method and a plasma chemical vapor deposition method are known.

Then, Patent Document 1 and Patent Document 2 each disclose a gas barrier laminated film in which a thin film layer of silicon nitride, silicon carbon oxynitride, or the like is formed by the aforementioned methods.

### PRIOR ART DOCUMENTS

### Patent Documents

Patent Document 1: JP-A-2011-231357

Patent Document 2: JP-A-2005-219427

### SUMMARY OF THE INVENTION

### Problems to be Solved by the Invention

However, when the a layer having a different function such as a transparent conductive layer is further formed on the gas barrier laminated film, an adhesion property has been insufficient.

The present invention has been devised in light of the circumstances, and it is an object of the present invention to provide a gas barrier laminated film that is excellent in adhesion to a transparent conductive layer while maintaining optical characteristics and flexibility.

### Means for Solving the Problems

In order to solve the problem, the present invention provides a laminated film including a flexible base material, and at least one thin film layer formed on at least one of surfaces of the base material, and

the at least one thin film layer satisfies all of the following conditions (i) and (ii):

(i) a silicon atom (Si), an oxygen atom (0) and a nitrogen atom (N) are contained,

(ii) when X-ray photoelectron spectrometry is conducted for a surface of the thin film layer, an atomic number ratio of carbon atoms to silicon atoms calculated from a wide scan spectrum satisfies a condition represented by the following formula (1):

0<C/Si≦0.2 (1).

In the laminated film of the present invention, preferably, an average atomic number ratio of the number of silicon atoms to a total number of silicon atoms, oxygen atoms, nitrogen atoms and carbon atoms (C) contained in the thin film layer satisfying conditions (i) and (ii) falls within the range of 0.1 to 0.5, an average atomic number ratio of the number of oxygen atoms to a total number of silicon atoms, oxygen atoms, nitrogen atoms and carbon atoms (C) contained in the thin film layer satisfying conditions (i) and (ii) falls within the range of 0.05 to 0.5, an average atomic number ratio of the number of nitrogen atoms to a total number of silicon atoms, oxygen atoms, nitrogen atoms and carbon atoms (C) contained in the thin film layer satisfying conditions (i) and (ii) falls within the range of 0.4 to 0.8, and an average atomic number ratio of the number of carbon atoms to a total number of silicon atoms, oxygen atoms, nitrogen atoms and carbon atoms (C) contained in the thin film layer satisfying conditions (i) and (ii) falls within the range of 0 to 0.05.

In the laminated film of the present invention, preferably, a refractive index of the thin film layer satisfying conditions (i) and (ii) falls within the range of 1.6 to 1.9.

In the laminated film of the present invention, preferably, a thickness of the thin film layer satisfying conditions (i) and (ii) is 80 nm or more, and silicon atoms and oxygen atoms are contained in a depth range up to 40 nm in a thickness direction toward inside the thin film layer satisfying conditions (i) and (ii) from a surface of the thin film layer satisfying conditions (i) and (ii), and an atomic number ratio of nitrogen atoms to silicon atoms falls within the range represented by the following formula (2):

N/Si≦0.2 (2).

Preferably, a thickness of the thin film layer satisfying conditions (i) and (ii) is 80 nm or more, and silicon atoms and oxygen atoms are contained in a depth range up to 40 nm in the thickness direction toward inside the thin film layer satisfying conditions (i) and (ii) from an interface between the thin film layer satisfying conditions (i) and (ii) and the base material or another thin film layer, and an atomic number ratio of nitrogen atoms to silicon atoms falls within the range represented by the following formula (3):

N/Si≦0.2 (3).

In the laminated film of the present invention, preferably, when infrared spectrometry is conducted for the thin film layer satisfying conditions (i) and (ii), an intensity ratio between a peak intensity (I) existing between 810 and 880 cm⁻¹ and a peak intensity (I′) existing between 2100 and 2200 cm⁻¹ falls within the range represented by the following formula (4):

0.05≦I′/I≦0.20 (4).

In the laminated film of the present invention, preferably, the thin film layer satisfying conditions (i) and (ii) is formed by an inductively-coupled plasma CVD method.

Moreover, a flexible electronic device using the laminated film of the present invention as a substrate is preferred.

### Effect of the Invention

According to the present invention, it is possible to provide a gas barrier laminated film that is excellent in adhesion to a transparent conductive layer while maintaining optical characteristics and flexibility. The laminated film of the present invention can be used as a substrate of a flexible electronic device, and is industrially very useful.

### BRIEF DESCRIPTION OF THE DRAWINGS

FIG. 1 shows one example of an inductively-coupled plasma CVD apparatus for producing a laminated film of the present embodiment.

FIG. 2 is a graph showing a silicon distribution curve, a nitrogen distribution curve, an oxygen distribution curve and a carbon distribution curve of a thin film layer in a laminated film 1 obtained in Example 1.

### MODE FOR CARRYING OUT THE INVENTION

### Laminated Film

The laminated film according to the present invention is the aforementioned laminated film.

An atomic number ratio of carbon atoms to silicon atoms calculated from a wide scan spectrum represents an atomic number ratio in an outermost surface of a thin film layer. The number of carbon atoms relative to the number of silicon atoms in the outermost surface of the thin film layer fall within a certain range such that the relation represented by formula (1) is satisfied, and as a result, impurities contained in a raw material formed in the outermost surface of the thin film layer, impurities occurring during deposition, impurities having adhered after deposition or the like reduce, and the laminated film becomes excellent in adhesion in forming a transparent conductive layer on the thin film layer. An element ratio between carbon atoms and silicon atoms preferably falls within the range of C/Si≦0.15, because impurities in the outermost surface of the thin film layer reduce. Moreover, the range of C/Si≧0.02 is preferred because wettability of the outermost surface of the thin film layer can be controlled. Here, a surface of the thin film layer means a surface of a laminate when the thin film layer exists in an outermost surface of the laminate, or means a surface which is to be the surface of the laminate when every layer existing on the thin film layer is removed from the laminated film in the case where another layer further exists on the thin film layer (on a surface farther from a base material in the thin film layer). In the case where another layer is formed on the thin film layer, it is preferred to measure the wide scan spectrum before forming another layer, and in the case where another layer has already been formed, every layer existing on the thin film layer can be removed from the laminated film to measure the wide scan spectrum.

The wide scan spectrum can be measured by X-ray photoelectron spectroscopy (Quantera SXM, available from ULVAC PHI). An AlKα ray (1486.6 eV, X-ray spot 100 μm) is used as an X-ray source, and a neutralized electron gun (1 eV), and a low speed Ar ion gun (10 V) are used for charge correction at the time of measurement. Regarding analysis after the measurement, spectrum analysis is conducted by using MultiPak V6.1A (ULVAC-PHI, Inc.), and the atomic number ratio of C to Si can be calculated by using peaks corresponding to binding energy of Si:2p, O:1s, N:1s, C:1s obtained from the measured wide scan spectrum.

As a technique for controlling the atomic number ratio represented by formula (1), a surface activating treatment for cleaning the thin film layer surface is preferred. Examples of the surface activating treatment include a corona treatment, a vacuum plasma treatment, an atmospheric pressure plasma treatment, a UV ozone treatment, a vacuum ultraviolet excimer lamp treatment, and a flame treatment.

The laminated film of the present invention is a laminated film in which at least one thin film layer is formed on one of two main surfaces of a flexible base material. Here, the layer means a layer produced by a single production method. In the laminated film, the thin film layer may be formed not only on one surface of the flexible base material but also on the other surface. Moreover, the thin film layer may be composed of a single layer or may be composed of a plurality of layers, and in the latter case, all the plurality of layers may be the same, or may be different from each other, or may be partially the same. The thin film layer preferably exists on an outermost surface of the laminated film. In this case, an effect of adhesion to a transparent conductive layer is enhanced.

The flexible base material is in the form of a film or a sheet, and examples of a material thereof include resin or a composite material containing resin.

Examples of the resin include polyethylene terephthalate (PET), polybutylene terephthalate (PBT), polyethylene naphthalate (PEN), acrylate, methacrylate, polycarbonate (PC), polyarylate, polyethylene (PE), polypropylene (PP), cyclic polyolefin (COP, COC), polyamide, aromatic polyamide, polystyrene, polyvinyl alcohol, saponificated ethylene-vinyl acetate copolymer, polyacrylonitrile, polyacetal, polyimide, polyether imide, polyamide imide, polyether sulfide (PES), and polyetheretherketone.

Moreover, examples of the composite material containing resin include a substrate of silicone resin such as polydimethylsiloxane, a substrate of organic-inorganic hybrid resin such as polysilsesquioxane, a glass composite substrate, and a glass epoxy substrate.

The material of the flexible base material may be of one kind or may be of two or more kinds.

Among these, as the material of the flexible base material, PET, PBT, PEN, cyclic polyolefin, polyimide, aromatic polyamide, a glass composite substrate or a glass epoxy substrate is preferred because of their high transparency and heat resistance and low coefficient of thermal expansion.

The flexible base material is preferably colorless and transparent because such a base material enables transmission and absorption of light. More specifically, total light transmission is preferably 80% or more, more preferably 85% or more. Moreover, a haze value is preferably 5% or less, more preferably 3% or less, further preferably 1% or less.

The flexible base material is preferably insulative because such a base material can be used for a base material of an electronic device or an energy device, and preferably has an electric resistivity of 10⁶ Ωcm or more.

The thickness of the flexible base material can be set appropriately in consideration of stability in producing the laminated film. For example, the thickness is preferably 5 to 500 μm, more preferably 10 to 200 μm, further preferably 50 to 100 μm because the film can be conveyed also in a vacuum.

Note that the flexible base material may have at least one selected from the group consisting of a primer coat layer and an undercoat layer. When these layers exist on the surface of the flexible base material, a base material including these layers is regarded as the flexible base material in the present invention. The primer coat layer and/or the undercoat layer is used for improving adhesiveness between the flexible base material and a first thin film layer and/or flatness. The primer coat layer and/or the undercoat layer can be formed by appropriately using a known primer coating agent, a known undercoating agent or the like.

As the flexible base material, a base material subjected to a liquid washing treatment for cleaning the surface of a thin film layer forming side is preferred because adhesiveness to the thin film layer improves. Examples of the liquid washing treatment include a pure water washing treatment, an ultrapure water washing treatment, an ultrasonic water washing treatment, a scrub washing treatment, a rinse washing treatment, and a double fluid rinse treatment.

As the flexible base material, a base material subjected to a surface activating treatment for cleaning the surface of a thin film layer forming side is preferred because adhesiveness to the thin film layer improves. Examples of the surface activating treatment include a corona treatment, a vacuum plasma treatment, an atmospheric pressure plasma treatment, a UV ozone treatment, a vacuum ultraviolet excimer lamp treatment, and a flame treatment.

Preferably, the thin film layer contains a silicon atom, an oxygen atom and a nitrogen atom, and is based on a compound represented by a general formula of SiO_{α}N_{β} because both flexibility and a gas barrier property can be achieved. Here, “be based on” means that the content of a component in question relative to the mass of all components of the material is greater than 50% by mass, preferably 70% or more by mass, more preferably 90% or more by mass. Moreover, in this general formula, a is selected from positive numbers of less than 1, and β is selected from positive numbers of less than 3. At least one of α and β in the general formula may be a constant value or may be varied in the thickness direction of the thin film layer.

Further, the thin film layer may contain other elements than a silicon atom, an oxygen atom and a nitrogen atom, for example, at least one selected from the group consisting of a carbon atom, a boron atom, an aluminum atom, a phosphorus atom, a sulfur atom, a fluorine atom and a chlorine atom.

The thin film layer may contain a silicon atom, an oxygen atom, a nitrogen atom and a hydrogen atom. In that case, the thin film layer is preferably based on a compound represented by a general formula of SiO_{α}N_{β}H_{γ}. In this general formula, α is selected from positive numbers of less than 1, β is selected from positive numbers of less than 3, and γ is selected from positive numbers of less than 10. At least one of α, β and γ in the general formula may be a constant value or may be varied in the thickness direction of the thin film layer.

Further, the thin film layer may contain other elements than a silicon atom, an oxygen atom, a nitrogen atom and a hydrogen atom, for example, at least one selected from a carbon atom, a boron atom, an aluminum atom, a phosphorus atom, a sulfur atom, a fluorine atom and a chlorine atom.

In the thin film layer, an average atomic number ratio of the number of silicon atoms to the total number of silicon atoms, oxygen atoms, nitrogen atoms and carbon atoms falls preferably within the range of 0.10 to 0.50, more preferably within the range of 0.15 to 0.45, further preferably within the range of 0.20 to 0.40.

In the thin film layer, an average atomic number ratio of the number of oxygen atoms to the total number of silicon atoms, oxygen atoms, nitrogen atoms and carbon atoms falls preferably within the range of 0.05 to 0.50, more preferably within the range of 0.10 to 0.45, further preferably within the range of 0.15 to 0.40.

In the thin film layer, an average atomic number ratio of the number of nitrogen atoms to the total number of silicon atoms, oxygen atoms, nitrogen atoms and carbon atoms falls preferably within the range of 0.40 to 0.80, more preferably within the range of 0.45 to 0.75, further preferably within the range of 0.50 to 0.70.

In the thin film layer, an average atomic number ratio of the number of carbon atoms to the total number of silicon atoms, oxygen atoms, nitrogen atoms and carbon atoms falls preferably within the range of 0 to 0.05, more preferably within the range of 0.005 to 0.04, further preferably within the range of 0.01 to 0.03.

Note that the average atomic number ratios Si, 0 and N can be determined by conducting XPS depth profile measurement in the following conditions, and determining average atomic concentrations in the thickness direction of respective atoms from obtained distribution curves of a silicon atom, a nitrogen atom, an oxygen atom and a carbon atom, and subsequently calculating the average atomic number ratios Si, O and N.

### <XPS Depth Profile Measurement>

Etching ionic species: argon (Ar⁺)

Etching rate (in terms of a SiO₂ thermally oxidized film): 0.05 nm/sec

Etching interval (in terms of SiO₂): 10 nm

X-ray photoelectron spectrometer: available from Thermo Fisher Scientific, model name “VG Theta Probe”

Irradiation X ray: single crystal spectroscopy AlKα

Spot of X-ray and size thereof: oval shape of 800×400 μm.

A refractive index of the thin film layer falls preferably within the range of 1.6 to 1.9, more preferably within the range of 1.65 to 1.85, further preferably within the range of 1.7 to 1.8 because a gas barrier property and transparency can be enhanced. Note that the refractive index of the thin film layer can be calculated by conducting evaluation by using spectroscopic ellipsometry, and determining the real part n of the complex refractive index at 550 nm.

Preferably, as will be described later, the thin film layer is formed by a plasma chemical vapor deposition method (plasma CVD method).

The thickness of the thin film layer is preferably 5 to 3000 nm, more preferably 10 to 2000 nm, further preferably 80 to 1500 nm, particularly preferably 100 to 1000 nm because a gas barrier property and transparency can be enhanced.

Preferably, the thickness of the thin film layer is 80 nm or more, silicon atoms and oxygen atoms are contained in the depth range up to 40 nm in the thickness direction toward inside the thin film layer from the surface of the thin film layer, and an atomic number ratio of nitrogen atoms to silicon atoms falls within the range of the following formula (2), because both flexibility and a gas barrier property can be achieved.

N/Si≦0.2 (2)

The atomic number ratio can be measured by the aforementioned XPS depth profile measurement.

In the depth range up to 40 nm in the thickness direction toward inside the thin film layer from the surface of the thin film layer, the film is based on a compound represented by a general formula of SiO_{α}. α is preferably a number of 1.5 to 3.0, more preferably a number of 2.0 to 2.5. α may be a constant value or may be varied in the depth up to 40 nm in the thickness direction toward inside the second thin film layer from a surface of the second thin film layer.

Preferably, the thickness of the thin film layer is 80 nm or more, silicon atoms and oxygen atoms are contained in the depth range up to 40 nm in the thickness direction toward inside the thin film layer from an interface between the thin film layer and the base material or another thin film layer, and an atomic number ratio of nitrogen atoms to silicon atoms falls within the range of the following formula (3), because both flexibility and a gas barrier property can be achieved.

N/Si≦0.2 (3)

The atomic number ratio can be measured by the aforementioned XPS depth profile measurement.

In the depth range up to 40 nm in the thickness direction toward inside the thin film layer from the interface between the thin film layer and the base material or another thin film layer, the film is based on a compound represented by a general formula of SiO_{α}. α is preferably a number of 1.5 to 3.0, more preferably a number of 2.0 to 2.5. α may be a constant value or may be varied in the depth up to 40 nm in the thickness direction toward inside the second thin film layer from the surface of the second thin film layer.

In the thin film layer, an intensity ratio I′/I between a peak intensity (I) existing between 810 to 880 cm⁻¹ and a peak intensity (I′) existing between 2100 to 2200 cm⁻¹ in an infrared absorption spectrum obtained by infrared spectrometry preferably falls within the range represented by the following formula (4) because both transparency and a gas barrier property can be achieved.

0.05≦I′/I≦0.20 (4)

Note that in the measurement of the infrared absorption spectrum of the thin film layer, a cyclic cycloolefin film (for example, ZEONOR ZF16 film available from ZEON CORPORATION) is used as the base material, and after the thin film layer is formed singly on the surface of the base material, the infrared absorption spectrum can be calculated. The infrared absorption spectrum can be measured by using a Fourier transformation type infrared spectrophotometer (FT/IR-460Plus, available from JASCO Corporation) equipped with an ATR attachment (PIKE MIRacle) using germanium crystals for a prism. Moreover, the thin film layer is obtained by forming an induction field by applying high-frequency power on an induction coil with use of a commonly used inductively-coupled plasma CVD apparatus, and introducing a source gas to generate plasma, and forming a thin film on the base material. When a production condition of the thin film layer is unknown, only the thin film layer may be taken off to measure the infrared absorption spectrum.

An absorption peak existing between 810 and 880 cm⁻¹ is imputed to Si—N, and an absorption peak existing between 2100 and 2200 cm⁻¹ is imputed to Si—H. That is, I′/I is preferably 0.20 or less in order that the thin film layer can have a denser structure from the viewpoint of enhancing a gas barrier property, and I′/I is also preferably 0.05 or more so as not to reduce light transmission in the visible light range from the viewpoint of enhancing transparency.

Note that the laminated film may have, in addition to the thin film layer, at least one selected from the group consisting of a heat sealable resin layer, an overcoat layer and an adhesive layer on the thin film layer as long as such a layer does not inhibit the effect of the present invention. When these layers exist on the surface of the thin film layer, a film including these layers is regarded as the laminated film in the present invention. The heat sealable resin layer can be formed by appropriately using a known heat sealable resin or the like. The overcoat layer is used for protecting the second thin film layer, or improving adhesiveness to another member and/or flatness. The overcoat layer can be formed by appropriately using a known overcoat agent or the like. The adhesive layer is used, for example, for mutual adhesion of a plurality of laminated films, or for adhesion of the laminated film to another member. The adhesive layer can be formed by appropriately using a known adhesive or the like.

Total light transmission is preferably 80% or more, more preferably 85% or more because the laminated film of the present invention has high transparency. The total light transmission can be measured by a direct reading haze computer (model HGM-2DP) available from Suga Test Instruments Co., Ltd.

### [Method for Producing Laminated Film]

The laminated film of the present invention can be produced by forming the thin film layer on the surface of the thin film layer forming side of the base material by a known vacuum deposition method such as a plasma CVD method. Among others, it is preferred to form the thin film layer by an inductively-coupled plasma CVD method. The inductively-coupled plasma CVD method is a technique for forming an induction field by applying high-frequency power on an induction coil, and generating plasma. Since the generated plasma is highly dense and low temperature plasma, and is also stable glow discharge plasma, the plasma is suited for forming a dense thin film on the flexible base material.

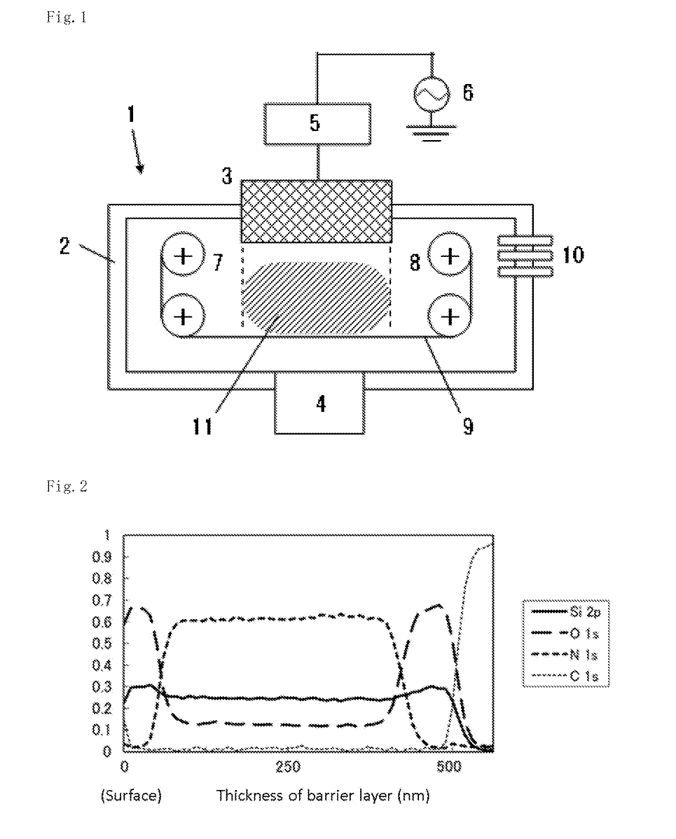

The thin film layer is formed by forming an induction field by applying high-frequency power on an induction coil with use of a commonly used inductively-coupled plasma CVD apparatus, and introducing a source gas to generate plasma, and forming a thin film on the flexible base material (for example, see JP-A-2006-164543). FIG. 1 shows one example of an inductively-coupled plasma CVD apparatus for producing the laminated film of the present embodiment. In a vacuum chamber 2, a delivery roll 7 and a winding roll 8 are disposed, and a base material 9 is continuously conveyed. Note that the delivery roll 7 and the winding roll 8 can be inverted depending on situations, and the delivery roll can be changed to the winding roll, and the winding roll can be changed to the delivery roll appropriately. Above a deposition part 11 where the thin film layer is formed on the base material 9, an induction coil 3 for generating a magnetic field via a rectangular dielectric window composed of aluminum oxide or the like is provided, and gas introducing piping 10 and a vacuum pump 4 for discharging excessive gas are provided. Note that a straightening vane for making the gas uniform may be provided near a part where the gas is introduced or discharged. Moreover, the induction coil 3 is connected with a high-frequency power source 6 via a matching box 5.

The laminated film of the present invention is produced by using this plasma CVD apparatus 1, in such a manner that a source gas is fed from the gas introducing piping 10 while the base material 9 is conveyed at a constant speed, and plasma is generated by the induction coil 3 in the deposition part 11, and the thin film layer composed by decomposing and recombining the source gas is formed on the base material 9.

In the formation of the thin film layer, the base material is conveyed at a constant speed in such a manner that the conveyance direction of the base material is parallel with one of two opposite sides of the rectangular dielectric window disposed above the deposition part 11 and is perpendicular to the other of the two opposite sides. As a result, during passage through the deposition part 11, a plasma density decreases directly below the two opposite sides of the dielectric window that are perpendicular to the conveyance direction of the base material, and in association with this, thin film layer composition after the decomposition and recombination of the source gas changes, and the second thin film layer and the third thin film layer can be formed stably.

The thin film layer is formed by using an inorganic silane gas, an ammonia gas, an oxygen gas and an inert gas as the source gas. The thin film layer is formed by flow of the source gas at a flow rate and a flow ratio that are each in the range used in an ordinary inductively-coupled plasma CVD method. Examples of the inorganic silane gas include hydrogenated silane gas and halogenated silane gas such as monosilane gas, disilane gas, trisilane gas, dichlorosilane gas, trichlorosilane gas, and tetrachlorosilane gas. Among these inorganic silane gases, monosialne gas and disilane gas are preferred because handleability of the compounds and denseness of the resultant thin film layer are excellent. These inorganic silane gases may be used singly or in combination of two or more kinds. Examples of the inert gas include nitrogen gas, argon gas, neon gas, and xenon gas.

Electric power supplied to electrodes can be adjusted appropriately depending on the kind of the source gas, an internal pressure of the vacuum chamber and the like, and is set, for example, at 0.1 to 10 kW, and a frequency of an alternate current is set, for example, at 50 Hz to 100 MHz. The electric power of 0.1 kW or more enhances an effect of suppressing generation of particles. The electric power of 10 kW or less enhances an effect of suppressing occurrence of wrinkles or damages on the flexible base material due to heat from the electrodes. Further, the AC frequency set at 1 MHz to 100 MHz may be used because decomposition efficiency of the source gas can be enhanced.

The internal pressure of the vacuum chamber (degree of vacuum) can be adjusted appropriately depending on the kind of the source gas or the like, and can be set, for example, at 0.1 Pa to 50 Pa.

Conveyance speed of the flexible base material can be adjusted appropriately depending on the kind of the source gas, the internal pressure of the vacuum chamber or the like, but the conveyance speed is preferably the same as conveyance speed of the base material when the base material is brought into contact with a conveyance roll.

It is preferred to form the thin film layer in a continuous deposition process, and it is more preferred to continuously form the thin film layer on a long base material while the long base material is conveyed continuously.

The thin film layer can further be formed from above by inverting the delivery roll and the winding roll and conveying the base material in the reverse direction after the thin film layer is formed while the flexible base material is conveyed from the delivery roll to the winding roll. Modification can be made appropriately depending on the desired number of laminated layers, the thickness and the conveyance speed.

The laminated film in the present invention can be used for application of packaging of foods, industrial articles, pharmaceuticals and the like for which a gas barrier property is required, and is preferably used as a flexible substrate of an electronic device such as a liquid crystal display device, a solar battery and an organic EL.

Note that when the laminated film is used as a flexible substrate of an electronic device, the device may be formed directly on the laminated film, or the laminated film may be overlapped from above after the device is formed on another substrate.

### EXAMPLES

Hereinafter, the preset invention will be described further in detail by way of Examples. Note that composition analysis of a thin film layer surface of a laminated film, and optical characteristics, a gas barrier property and adhesion durability of the laminated film were evaluated by the following methods.

### <X-Ray Photoelectron Spectrometry of Thin Film Layer Surface>

An atomic number ratio (element ratio in a thin film layer surface) in a thin film layer surface of a laminated film was measured by X-ray photoelectron spectroscopy (Quantera SXM available from ULVAC PHI). An AlKα ray (1486.6 eV, X-ray spot 100 μm) was used as an X-ray source, and a neutralized electron gun (1 eV), and a low speed Ar ion gun (10 V) were used for charge correction at the time of measurement. Regarding analysis after the measurement, spectrum analysis was conducted by using MultiPak V6.1A (ULVAC-PHI, Inc.), and a surface atomic number ratio of C to Si was calculated by using peaks corresponding to binding energy of Si:2p, O:1s, N:1s, C:1s obtained from the measured wide scan spectrum. In the calculation of the surface atomic number ratio, an average value of five measurements was adopted.

### <Optical Characteristics of Laminated Film>

Optical characteristics of a laminated film were measured by a direct reading haze computer (model HGM-2DP) available from Suga Test Instruments Co., Ltd. After the background was measured in absence of a sample, the laminated film was set in a sample holder, and the measurement was conducted, and total light transmission was determined.

### <Gas Barrier Property of Laminated Film>

A gas barrier property of a laminated film was measured by a calcium corrosion method (method described in JP-A-2005-283561) in a condition of a temperature of 40° C. and humidity of 90% RH, and water vapor permeability (P1) of the laminated film was determined.

### <Flexibility of Laminated Film>

Flexibility of a laminated film was determined in the following manner. In the environment at a temperature of 23° C. and humidity of 50% RH, the laminated film was wound once around a bar available from SUS and having a diameter of 30 mm such that a thin film layer was outside, and water vapor permeability (P2) was determined for the laminated film by a calcium corrosion method (method described in JP-A-2005-283561) in a condition of a temperature of 40° C. and humidity of 90% RH, and a ratio (P2/P1) of the water vapor permeability (P2) to water vapor permeability before winding was determined and indicated by percentage.

### <Adhesion Durability of Laminated Film/Transparent Conductive Layer>

A water/alcohol dispersion containing poly (3,4-ethylenedioxythiophene)-poly (styrene sulfonate) (Product name: CLEVIOS P VP.AI4083, available from Heraeus Precious Metals) was applied on a thin film layer of a laminated film by spin coating (rotation number 1500 rpm, rotation time 30 seconds), and subsequently subjected to drying for 1 hour at 130° C. to provide a transparent conductive layer having a thickness of 35 nm. The case where the obtained laminated film was uniformly formed on the laminated film without cissing, and peeling of the transparent conductive layer was not observed after storage for 48 hours at a temperature of 85° C. and humidity of 85% RH was evaluated as acceptance, and every case other than that was evaluated as non-acceptance.

### Example 1

A biaxially-oriented polyethylene naphthalate film (Teonex Q65FA, available from Teijin DuPont Films Japan Limited, thickness 100 μm, width 350 mm, length 100 m) was used as a base material, and was mounted on a delivery roll disposed in a vacuum chamber, so as to make it possible to continuously convey the base material to a winding roll through a thin film layer deposition zone. After the mounting of the base material, the vacuum chamber was evacuated to 1×10⁻³ Pa or less, and subsequently a thin film layer was deposited on the base material while the base material was conveyed at a constant speed of 0.1 m/min. The base material was conveyed in such a manner that the conveyance direction of the base material was parallel with one of two opposite sides of a rectangular dielectric window disposed above the thin film layer deposition zone and was perpendicular to the other of the two opposite sides.

Regarding the deposition of the thin film layer, the thin film layer was formed on the base material by an inductively-coupled plasma CVD method using glow discharge plasma. The biaxially-oriented polyethylene naphthalate film used as the base material had an asymmetrical structure in which one surface was subjected to an easily-adhesive treatment, and the thin film layer was deposited on a surface that was not subjected to the easily-adhesive treatment. In the deposition, monosilane gas was introduced at 100 sccm (Standard Cubic Centimeter per Minute, 0° C., 1 atmospheric pressure basis), ammonia gas was introduced at 500 sccm, and oxygen gas was introduced at 0.75 sccm into the deposition zone, and electric power of 1.0 kW at a frequency of 13.56 kHz was supplied to an induction coil to discharge electricity and generate plasma. Then, the displacement was regulated such that an internal pressure of the vacuum chamber became 1 Pa, and subsequently the thin film layer was formed on the conveyed base material by the inductively-coupled plasma CVD method to obtain a laminated film 1. Note that the thickness of the thin film layer in the laminated film 1 was 500 nm.

XPS depth profile measurement was conducted for the laminated film 1 in the following conditions, and distribution curves of a silicon atom, a nitrogen atom, an oxygen atom and a carbon atom were obtained.

### <XPS Depth Profile Measurement>

Etching ionic species: argon (Ar⁺)

Etching rate (in terms of a SiO₂ thermally oxidized film): 0.05 nm/sec

Etching interval (in terms of SiO₂): 10 nm

X-ray photoelectron spectrometer: available from Thermo Fisher Scientific, model name “VG Theta Probe”

Irradiation X ray: single crystal spectroscopy AlKα

Spot of X-ray and size thereof: oval shape of 800×400 μm.

The obtained distribution curves of a silicon atom, a nitrogen atom, an oxygen atom and a carbon atom are shown in FIG. 2 as a graph plotting atomic number ratios of respective atoms on a vertical axis, and sputtering time (minute) on a horizontal axis. FIG. 2 also shows a relation between a density of each atom and the distance from a surface of the thin film layer (nm). That is, FIG. 2 is a graph showing a silicon distribution curve, a nitrogen distribution curve, an oxygen distribution curve and a carbon distribution curve of the thin film layer in the laminated film 1 obtained in Example 1. Note that the “distance (nm)” on the horizontal axis of the graph in FIG. 2 is a value determined by calculation from sputtering time and sputtering speed.

As is clear from the results shown in FIG. 2, it was made clear that the thin film layer of the laminated film 1 satisfied N/Si≦0.2 in the depth range up to 40 nm in the thickness direction toward inside the thin film layer from the surface of the thin film layer, and in the depth range up to 40 nm in the thickness direction toward inside the thin film layer from an interface between the thin film layer and the base material.

The thin film layer surface of the laminated film 1 was subjected to a UV-O₃ treatment for 600 seconds by using a UV ozone washing device UV-312 available from Technovision, Inc. to obtain a laminated film 2. The results of an element ratio (surface composition) of the thin film layer surface, optical characteristics, a gas barrier property, flexibility and an adhesion property of the laminated film 2 are shown in Table 1.

Moreover, in the case where a cyclic cycloolefin film (for example, ZEONOR ZF16 film available from ZEON CORPORATION, thickness 100 μm, width 350 mm, length 100 m) was used as the base material in order to conduct infrared spectrometry for the thin film layer, the same operation was also conducted to obtain a laminated film 3. Note that the thickness and a configuration of a thin film layer in the laminated film 3 were the same as those in the laminated film 1.

Infrared spectrometry was conducted for the laminated film 3 in the following conditions.

### <Infrared Spectrometry of Thin Film Layer>

Infrared spectrometry was conducted by a Fourier transformation type infrared spectrophotometer (FT/IR-460Plus, available from JASCO Corporation) equipped with an ATR attachment (PIKE MIRacle) using germanium crystals as a prism.

An absorption intensity ratio I′/I between a peak intensity (I) existing between 810 and 880 cm⁻¹ and a peak intensity (I′) existing between 2100 and 2200 cm⁻¹ was determined from the obtained infrared absorption spectrum, and the result was I′/I=0.11.

Evaluation was conducted for the thin film layer of the laminated film 2 by using spectroscopic ellipsometry (GRS-5 available from SOPRA). From the real part n of the complex refractive index at 550 nm, a refractive index was 1.75.

### Comparative Example 1

A laminated film 4 was obtained by the same method as in Example 1 except that the UV-O₃ treatment was conducted for 10 seconds instead of conducting the UV-O₃ treatment for 600 seconds. The results of an element ratio (surface composition) of a thin film layer surface, optical characteristics, a gas barrier property, flexibility and an adhesion property of the laminated film 4 are shown in Table 1.

A refractive index of a thin film layer of the laminated film 4 was 1.75.

### Comparative Example 2

A laminated film 5 was obtained by the same method as in Example 1 except that the UV-O₃ treatment was not conducted instead of conducting the UV-O₃ treatment for 600 seconds. The results of an element ratio (surface composition) of a thin film layer surface, optical characteristics, a gas barrier property, flexibility and an adhesion property of the laminated film 5 are shown in Table 1.

A refractive index of a thin film layer of the laminated film 5 was 1.75.

TABLE 1

| | | | | | Adhesion |
|---|---|---|---|---|---|
| | Thin film | Optical | Gas | | property to |
| | layer surface | character- | barrier | Flexi- | transparent |
| | element ratio | istics | property | bility | conductive |
| | (C/Si) | (%) | (g/m² · day) | (%) | layer |
| Example 1 | 0.11 | 89% | 2 × 10⁻⁴ | 100 | Acceptance |
| Compar- | 0.64 | 89% | 2 × 10⁻⁴ | 100 | Non- |
| ative | | | | | acceptance |
| Example 1 | | | | | |
| Compar- | 0.64 | 89% | 2 × 10⁻⁴ | 100 | Non- |
| ative | | | | | acceptance |
| Example 2 | | | | | |

It was possible to confirm from the results that the laminated film according to the present invention has an excellent adhesion property to a transparent conductive film formed on the laminated film without impairing optical characteristics such as transparency, a gas barrier property such as water vapor permeability and flexibility.

### INDUSTRIAL APPLICABILITY

The present invention can be applied to a gas barrier film.

### DESCRIPTION OF REFERENCE SIGNS

1 plasma CVD apparatus
2 Vacuum chamber
3 Induction coil, dielectric window
4 Vacuum pump (evacuation)
5 Matching box
6 High-frequency power source
7 Delivery roll
8 Winding roll
9 Base material
10 Gas introducing piping
11 Deposition part

1. A laminated film comprising a flexible base material, and at least one thin film layer formed on at least one of surfaces of the base material, wherein
the at least one thin film layer satisfies all of the following conditions (i) and (ii):
(i) a silicon atom (Si), an oxygen atom (0) and a nitrogen atom (N) are contained,
(ii) when X-ray photoelectron spectrometry is conducted for a surface of the thin film layer, an atomic number ratio of carbon atoms to silicon atoms calculated from a wide scan spectrum satisfies a condition represented by the following formula (1):
0<C/Si≦0.2 (1).

2. The laminated film according to claim 1, wherein an average atomic number ratio of the number of silicon atoms to a total number of silicon atoms, oxygen atoms, nitrogen atoms and carbon atoms (C) contained in the thin film layer satisfying conditions (i) and (ii) falls within the range of 0.10 to 0.50; an average atomic number ratio of the number of oxygen atoms to a total number of silicon atoms, oxygen atoms, nitrogen atoms and carbon atoms (C) contained in the thin film layer satisfying conditions (i) and (ii) falls within the range of 0.05 to 0.50; an average atomic number ratio of the number of nitrogen atoms to a total number of silicon atoms, oxygen atoms, nitrogen atoms and carbon atoms (C) contained in the thin film layer satisfying conditions (i) and (ii) falls within the range of 0.40 to 0.80; and an average atomic number ratio of the number of carbon atoms to a total number of silicon atoms, oxygen atoms, nitrogen atoms and carbon atoms (C) contained in the thin film layer satisfying conditions (i) and (ii) falls within the range of 0 to 0.05.

3. The laminated film according to claim 1, wherein a refractive index of the thin film layer satisfying conditions (i) and (ii) falls within the range of 1.6 to 1.9.

4. The laminated film according to claim 1, wherein a thickness of the thin film layer satisfying conditions (i) and (ii) is 80 nm or more, and silicon atoms and oxygen atoms are contained in a depth range up to 40 nm in a thickness direction toward inside the thin film layer satisfying conditions (i) and (ii) from a surface of the thin film layer satisfying conditions (i) and (ii), and an atomic number ratio of nitrogen atoms to silicon atoms falls within the range represented by the following formula (2):
N/Si≦0.2 (2).

5. The laminated film according to claim 1, wherein a thickness of the thin film layer satisfying conditions (i) and (ii) is 80 nm or more, and silicon atoms and oxygen atoms are contained in a depth range up to 40 nm in the thickness direction toward inside the thin film layer satisfying conditions (i) and (ii) from an interface between the thin film layer satisfying conditions (i) and (ii) and the base material or another thin film layer, and an atomic number ratio of nitrogen atoms to silicon atoms falls within the range represented by the following formula (3):
N/Si≦0.2 (3).

6. The laminated film according to claim 1, wherein when infrared spectrometry is conducted for the thin film layer satisfying conditions (i) and (ii), an intensity ratio between a peak intensity (I) existing between 810 and 880 cm⁻¹ and a peak intensity (I′) existing between 2100 and 2200 cm⁻¹ falls within the range represented by the following formula (4):
0.05≦I′/I≦0.20 (4).

7. The laminated film according to claim 1, wherein the thin film layer satisfying conditions (i) and (ii) is formed by an inductively-coupled plasma CVD method.

8. A flexible electronic device using the laminated film according to claim 1 as a substrate.
